(19) United States
(12) Patent Application Publication
(10) Pub. No.: US 2015/0303130 A1
(43) Pub. Date: Oct. 22, 2015

(54) Semiconductor Package and Method of Manufacturing the Same

(71) Applicant: Dongbu Hitek Co., Ltd., Seoul (KR)

(72) Inventors: Jun Il Kim, Gyeonggi-do (KR); Sung Jin Kim, Gyeonggi-do (KR); Hag Mo Kim, Gyeonggi-do (KR)

(21) Appl. No.: 14/477,420

(22) Filed: Sep. 4, 2014

(30) Foreign Application Priority Data
Apr. 16, 2014 (KR) 10-2014-0045168

(51) Int. Cl. H01L 23/373; H01L 23/00; H01L 21/56; H01L 23/29; H01L 23/31; H01L 21/3205; H01L 23/538; H01L 23/367

(52) U.S. Cl. CPC H01L 23/3737; H01L 23/5387; H01L 23/5386; H01L 24/17; H01L 23/367; H01L 23/293; H01L 23/3157; H01L 24/81; H01L 21/3205; H01L 21/563; H01L 2224/13144; H01L 2924/014; H01L 2224/16227; H01L 2224/81801; H01L 2924/0665

(57) ABSTRACT

Disclosed are a semiconductor package and a method of manufacturing the same. The semiconductor package includes a flexible substrate provided with signal lines, a semiconductor device bonded on the flexible substrate and configured to be connected to the signal lines through at least one of gold bumps or solder bumps, and a heat dissipation layer formed on at least a portion of the flexible substrate and at least a portion of the semiconductor device. The heat dissipation layer is formed by coating a heat dissipation paint composition and curing the heat dissipation paint composition. The heat dissipation paint composition includes an epichlorohydrin bisphenol A resin, a modified epoxy resin, a curing agent, a curing accelerator and a heat dissipation filler.

### CROSS-REFERENCE TO RELATED APPLICATION

This application claims priority to Korean Patent Application No. 10-2014-0045168 filed on Apr. 16, 2014 and all the benefits accruing therefrom under 35 U.S.C. §119, the contents of which are incorporated by reference in their entirety.

### BACKGROUND

The present disclosure relates to a semiconductor package and a method of manufacturing the same. More particularly, the present disclosure relates to a semiconductor package configured to be mounted on a flexible substrate such as a chip on film (COF) tape, or a tape carrier package (TCP) tape, and a method of manufacturing the same.

Display apparatuses such as liquid crystal displays (LCD) may include a liquid crystal display panel and a backlight unit disposed at the rear of the liquid crystal display panel. Semiconductor devices such as a driver integrated circuit (IC) may be used to drive the liquid crystal display panel. Such semiconductor devices may be connected to the liquid crystal display panel by applying a packaging technique including COF, TCP, chip on glass (COG), and the like.

High resolution display devices may require an increased driving load to be provided by the semiconductor device. In the particular case of COF-type semiconductor packages, this increased driving load may cause increased heat generation, leading to problems associated with the need for increased heat dissipation.

To address the need for increased heat dissipation, some prior art methods have been developed that involve the addition of a heat sink using an adhesion member. For example, Korean Laid-Open Patent Publication No. 10-2009-0110206 discloses a COF type semiconductor package including a flexible substrate, a semiconductor device mounted on the top surface of the flexible substrate and a heat sink mounted on the bottom surface of the flexible substrate using an adhesion member.

However, heat sinks mounted on the bottom surface of a flexible substrate may be inefficient due to the relatively low thermal conductivity of the flexible substrate. In addition, such heat sinks typically have a plate shape made by using a metal such as aluminum, which may reduce the flexibility of the COF-type semiconductor package. Furthermore, over time and through normal use, the heat sink may become separated from the flexible substrate.

### SUMMARY

The present disclosure provides a semiconductor package that improves the heat dissipation efficiency of a semiconductor device and a method of manufacturing the same.

In accordance with some exemplary embodiments, a semiconductor package may include a flexible substrate provided with signal lines, a semiconductor device bonded on the flexible substrate and configured to be connected to the signal lines through gold bumps or solder bumps, and a heat dissipation layer formed on at least a portion of the flexible substrate and at least a portion of the semiconductor device. In this case, the heat dissipation layer is formed by coating a heat dissipation paint composition including an epichlorohydrin bisphenol A resin, a modified epoxy resin, a curing agent, a curing accelerator and a heat dissipation filler, and curing the coated heat dissipation paint composition.

In some exemplary embodiments, the heat dissipation paint composition may include approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator and the remaining amount of the heat dissipation filler.

In some exemplary embodiments, the modified epoxy resin may be a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), a urethane modified epoxy resin or a silicon modified epoxy resin.

In exemplary embodiments, the curing agent may be a novolac type phenolic resin.

In some exemplary embodiments, the curing accelerator may be an imidazole-based curing accelerator or an amine-based curing accelerator.

In some exemplary embodiments, the heat dissipation filler may include aluminum oxide having a particle size of approximately 0.01 μm to approximately 50 μM.

In some exemplary embodiments, the heat dissipation layer may include a first heat dissipation layer formed on at least a portion of at least one side surface of the semiconductor device and on at least a portion of the flexible substrate, and a second heat dissipation layer formed on at least a portion of a top surface of the semiconductor device.

In some exemplary embodiments, the semiconductor package may further include an underfill layer filling a space defined between the semiconductor device and the flexible substrate.

In some exemplary embodiments, the heat dissipation layer and the underfill layer may both be formed by using the heat dissipation paint composition.

In accordance with some exemplary embodiments, a method of manufacturing a semiconductor package may include bonding a semiconductor device on a flexible substrate provided with signal lines. The semiconductor device may be configured to be connected to the signal lines through gold bumps or solder bumps. The method may also include forming a heat dissipation layer by coating a heat dissipation paint composition on at least a portion of the semiconductor device and on at least a portion of a top surface of the flexible substrate adjacent to the semiconductor device, and curing the heat dissipation layer. The heat dissipation paint composition includes an epichlorohydrin bisphenol A resin, a modified epoxy resin, a curing agent, a curing accelerator and a heat dissipation filler.

In some exemplary embodiments, the forming of the heat dissipation layer may include coating the heat dissipation paint composition on a portion of at least one side surface of the semiconductor device and on at least a portion of the flexible substrate, and coating the heat dissipation paint composition on at least a portion of a top surface of the semiconductor device.

In some exemplary embodiments, the forming of the heat dissipation layer may include positioning a mask on the flexible substrate. The mask may define an opening through which the semiconductor device and the portion of the top surface of the flexible substrate are exposed. The forming of the heat dissipation layer may also include filling up the opening with the heat dissipation paint composition using a squeegee.

In some exemplary embodiments, the method of manufacturing a semiconductor package may further include forming an underfill layer filling a space defined between the semiconductor device and the flexible substrate, and curing the underfill layer.

In some exemplary embodiments, the underfill layer may be obtained by injecting an underfill resin between the semiconductor device and the flexible substrate.

In some exemplary embodiments, the method of manufacturing a semiconductor package may further include forming an underfill layer by coating the heat dissipation paint composition on at least a portion of an area of the flexible substrate where the semiconductor device is to be bonded. The semiconductor device may be bonded so that the gold bumps or the solder bumps may be connected to the signal lines through the underfill layer.

In some exemplary embodiments, the heat dissipation paint composition may include approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator and the remaining amount of the heat dissipation composition may be heat dissipation filler.

In some exemplary embodiments, the modified epoxy resin may be a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), a urethane modified epoxy resin or a silicon modified epoxy resin.

In some exemplary embodiments, the curing agent may be a novolac type phenolic resin.

In some exemplary embodiments, the curing accelerator may be an imidazole-based curing accelerator or an amine-based curing accelerator.

In some exemplary embodiments, the heat dissipation filler may include aluminum oxide having a particle size of approximately 0.01 μm to approximately 50 μm.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWINGS

Exemplary embodiments can be understood in more detail from the following description taken in conjunction with the accompanying drawings, in which:

FIGS. 1 to 4 depict schematic cross-sectional views for explaining a method of manufacturing a semiconductor package in accordance with some exemplary embodiments;

FIGS. 5 and 6 depict photographic images for explaining the semiconductor package manufactured in accordance with FIGS. 1 to 4;

FIGS. 7 and 8 depict schematic cross-sectional views for explaining a semiconductor package in accordance with some exemplary embodiments; and

FIGS. 9 to 11 depict schematic cross-sectional views for explaining a method of manufacturing a semiconductor package in accordance with some exemplary embodiments.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when a layer, a film, a region or a plate is referred to as being ‘on’ another layer, film, region, or plate, it can be directly on the other one, or one or more intervening layers, films, regions or plates may also be present. Otherwise, when an element is referred to as being directly on another element, no intervening elements may be present. It will be understood that, although ordinal numbers such as first, second, third, etc. may be used herein to describe various elements, components, regions, layers and/or sections, these terms are used merely for ease of reference and/or antecedent basis for particular elements, regions, layers, and/or sections. As such, these terms should not be construed to describe or imply a particular sequence or ordering of elements, components, regions, layers and/or sections unless explicitly stated.

The terminology used herein is for the purpose of describing particular example embodiments only and is not intended to limit the present inventive concept. Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments are described herein with reference to schematic illustrations of idealized example embodiments. Variations from the sizes and shapes of the illustrations as a result, for example, of manufacturing techniques and/or tolerances, are to be expected. Furthermore, these schematics are not drawn to scale. Thus, example embodiments should not be construed as limited to the particular sizes or shapes of regions illustrated herein. These example embodiments may include deviations in shapes that result, for example, from manufacturing. As such, it should be appreciated that the regions illustrated in the figures are not intended to illustrate the actual size or shape of a region of a device and are not intended to limit the scope of the present inventive concept or claims.

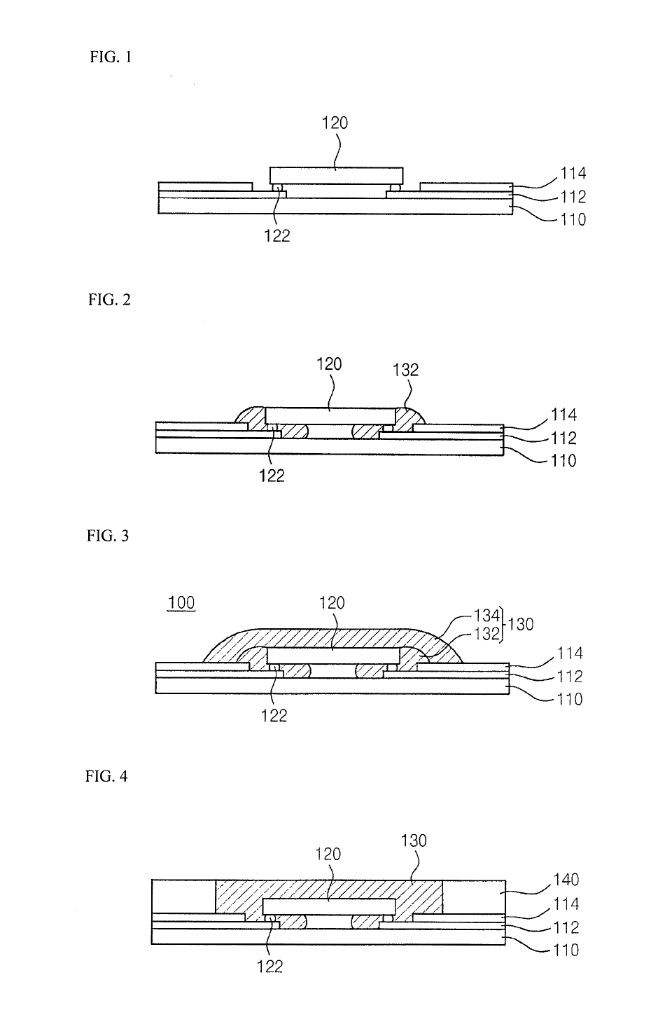

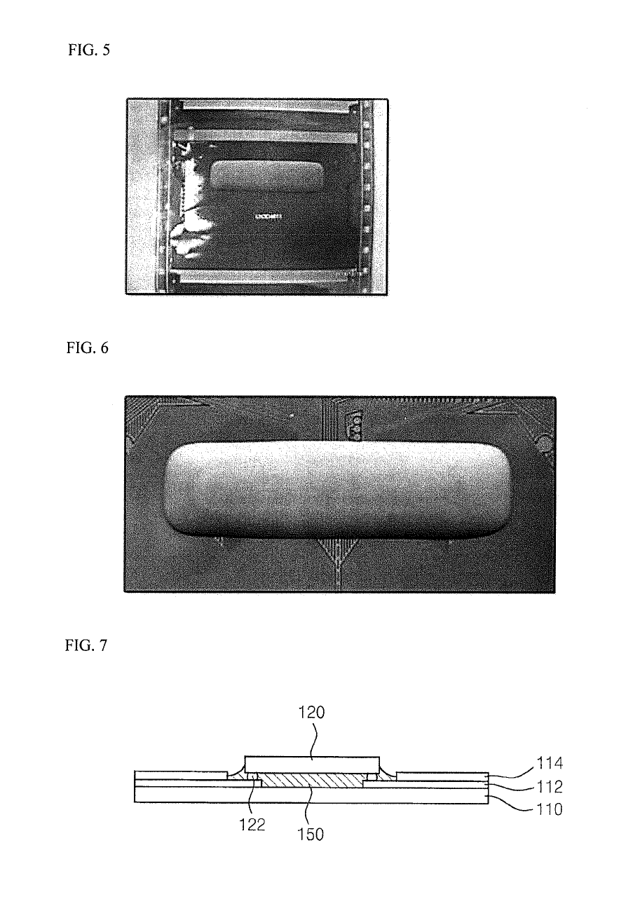

FIGS. 1 to 4 depict schematic cross-sectional views for explaining a method of manufacturing a semiconductor package in accordance with an exemplary embodiment, and FIGS. 5 and 6 are photographic images for explaining the semiconductor package manufactured in accordance with FIGS. 1 to 4.

Turning to FIG. 1, a semiconductor device 120 may be mounted on a flexible substrate 110. For example, a COF tape may be used as the flexible substrate 110 to manufacture a COF-type semiconductor package. Alternatively, various other suitable flexible materials such as a TCP tape, a ball grid array (BGA) tape, an application specific integrated circuit (ASIC) tape, or a flexible printed circuit (FPC), and the like may be used as the flexible substrate 110.

Signal lines 112 and an insulating layer 114 may be formed on the flexible substrate 110. The signal lines 112 may include conductive matters. The insulating layer 114 may be configured to passivate the signal lines 112. The semiconductor device 120 may be bonded on the flexible substrate 110 so as to be connected to the signal lines 112 through gold bumps and/or solder bumps 122. For example, the signal lines 112 may be formed by using a conductive material such as copper, and the insulating layer 114 may be a surface resist layer (SR layer) or a solder resist layer.

FIGS. 2 and 3 depict formation of a heat dissipation layer 130 for dissipating heat generated by the semiconductor device 120. The heat dissipation layer 130 may be formed on the semiconductor device 130 by a potting process.

In accordance with some example embodiments, as shown in FIG. 2 a heat dissipation paint composition may be coated on the side surfaces of the semiconductor device 120 and on a portion of the flexible substrate 110 adjacent to the side surfaces of the semiconductor device 120 to form a first heat dissipation layer 132. Then, as shown in FIG. 3, the heat dissipation paint composition may be coated on the top surface of the semiconductor device 120 to form a second heat dissipation layer 134.

A potting unit configured to form the heat dissipation layer 130 may be moved in a vertical direction and a horizontal direction by a driving part such as a Cartesian coordinate robot. In some embodiments, the potting unit may move in the horizontal direction along the side surfaces of the semiconductor device 120 to form the first heat dissipation layer 132 and may move in the horizontal direction above the semiconductor device 120 to form the second heat dissipation layer 134.

In accordance with some example embodiments, the heat dissipation layer 130 may be formed by a screen printing process as shown in FIG. 4. For example, a mask 140 that forms an opening may be configured to expose the semiconductor device 120 and a portion of the flexible substrate 110 adjacent to the semiconductor device 120. The mask 140 may be positioned on the flexible substrate 110, and the opening may be filled with the heat dissipation paint composition to form the heat dissipation layer 130. After depositing the heat dissipation paint composition in the opening, a squeegee may be used to remove excess heat dissipation paint composition deposited on the mask above or otherwise outside of the opening.

The heat dissipation paint composition may infiltrate into a space between the flexible substrate 110 and the semiconductor device 120 during the potting process or the screen printing process. However, if the infiltration of the heat dissipation paint composition is insufficient, an air gap may be formed between the flexible substrate 110 and the semiconductor device 120 as depicted in FIG. 4.

In accordance with some example embodiments, the viscosity of the heat dissipation paint composition may be controlled to reduce the likelihood of an air gap being formed between the flexible substrate 110 and the semiconductor device 120, as a reduced viscosity may allow the heat dissipation paint composition to more easily flow into the area between the flexible substrate 110 and the semiconductor device 120. The elimination of this gap may result in an underfill layer being formed between the flexible substrate 110 and the semiconductor device 120 by the infiltration of the heat dissipation paint composition.

Referring to FIGS. 5 and 6, after forming the heat dissipation layer 130 as described above, the heat dissipation layer 130 may be cured in a curing chamber at the temperature of approximately 140° C. to approximately 160° C., for example, at approximately 150° C., thereby forming the heat dissipation layer 130 having improved heat dissipation properties and flexibility on the semiconductor device 120 and the flexible substrate 110.

In accordance with an example embodiment, the heat dissipation paint composition may include an epichlorohydrin bisphenol A resin, a modified epoxy resin, a curing agent, a curing accelerator, a heat dissipation filler, and combinations thereof. Particularly, the heat dissipation paint composition may include approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator and the remaining amount of the heat dissipation filler.

The use of epichlorohydrin bisphenol A resin may improve the adhesiveness of the heat dissipation paint composition, and the use of modified epoxy resin may improve the flexibility and the elasticity of the heat dissipation layer thus cured. Particularly, the modified epoxy resin may include a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, an acrylic rubber modified epoxy resin (ARMER), an urethane modified epoxy resin, a silicon modified epoxy resin, and/or the like or combinations thereof.

The curing agent may include a novolac type phenolic resin. For example, the curing agent may include a novolac type phenolic resin obtained by reacting one of phenol, cresol and bisphenol A with formaldehyde.

The curing accelerator may include an imidazole-based curing accelerator or an amine-based curing accelerator. For example, the imidazole-based curing accelerator may include imidazole, isoimidazole, 2-methylimidazole, 2-ethyl-4-methylimidazole, 2,4-dimethylimidazole, butylimidazole, 2-methylimidazole, 2-phenylimidazole, 1-benzyl-2-methylimidazole, 1-propyl-2-methylimidazole, 1-cyanoethyl-2-methylimidazole, 1-cyanoethyl-2-ethyl-4-methylimidazole, phenylimidazole, benzylimidazole, and/or the like or combinations thereof.

The amine-based curing accelerator may include an aliphatic amine, a modified aliphatic amine, an aromatic amine, a secondary amine, a tertiary amine, and the like. For example, the amine-based curing accelerator may include benzyldimethylamine, triethanolamine, triethylenetetramine, diethylenetriamine, triethylamine, dimethylaminoethanol, m-xylenediamine, isophorone diamine, and the like or combinations thereof.

The heat dissipation filler may include aluminum oxide having a particle size of approximately 0.01 μm to approximately 50 μm, and preferably, of approximately 0.01 μm to approximately 20 The heat dissipation filler may be used to improve the thermal conductivity of the cured heat dissipation layer 130. Particularly, the heat dissipation paint composition may include approximately 75 wt % to approximately 95 wt % of the heat dissipation filler based on the total amount of the heat dissipation paint composition, and so, the thermal conductivity of the heat dissipation layer 130 may be controlled in the range of approximately 2.0 W/mK to approximately 3.0 W/mK. In addition, the epichlorohydrin bisphenol A resin and the modified epoxy resin may be added to ensure the adhesiveness of the heat dissipation layer 130 is between approximately 8 MPa to approximately 12 MPa.

The viscosity of the heat dissipation paint composition may be controlled to be in a range of approximately 100 Pas to approximately 200 Pas, and the heat dissipation paint composition may be cured in a temperature range of approximately 140° C. to approximately 160° C. The viscosity of the heat dissipation paint composition may be measured by using a B type rotational viscometer. The viscosity of the heat dissipation paint composition may be particularly measured at a rotor rotation velocity of approximately 20 rpm at a temperature of approximately 23° C.

In accordance with an example embodiment as described above, the heat dissipation layer 130 may be formed directly on the top surface and the side surfaces of the semiconductor device 120, improving the heat dissipation efficiency of. In addition, since the heat dissipation layer 130 provides improved flexibility and adhesiveness, the likelihood of separation from the flexible substrate 110 may be reduced and the flexibility of the semiconductor package 100 may be improved over conventional techniques.

An apparatus (not shown) for manufacturing the heat dissipation layer 130 may include a potting module or a screen printing module configured to form the heat dissipation layer 130 and a curing module configured to cure the heat dissipation layer 130. Additionally, the apparatus may include an unwinder module including a supplying reel configured to supply a flexible substrate 110 in tape form and a rewinder module including a recovering reel configured to recover the flexible substrate 110.

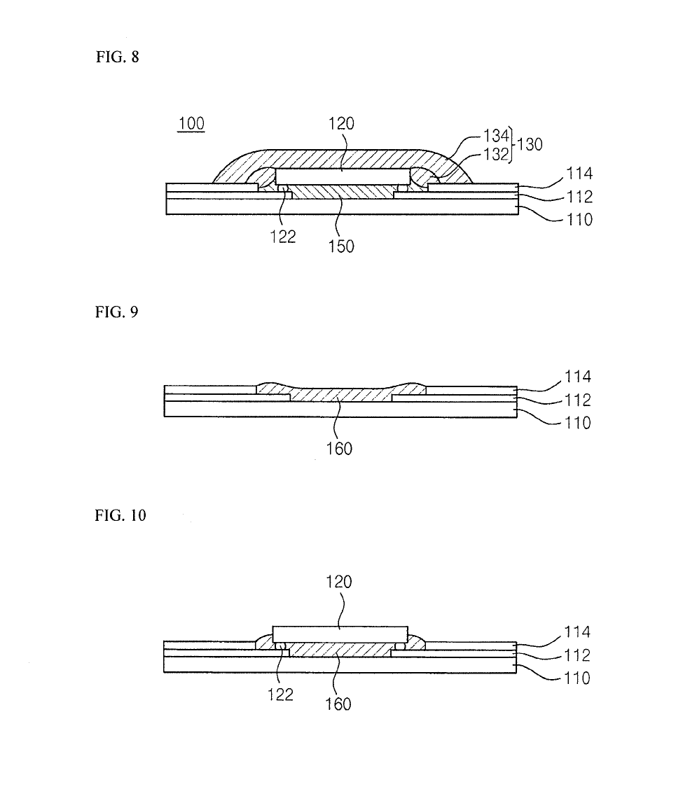

FIGS. 7 and 8 depict schematic cross-sectional views of a semiconductor package in accordance with some example embodiments.

Referring to FIG. 7, a semiconductor package 100 in accordance with some example embodiments may include an underfill layer 150 filling a space between the semiconductor device 120 and the flexible substrate 110.

The underfill layer 150 may be formed by injecting an underfill resin into the space between the semiconductor device 120 and the flexible substrate 110. After injecting the underfill resin, the underfill resin may be cured at a temperature of approximately 150° C.

In particular, a portion of the top surface of the flexible substrate 110 adjacent to a side surface of the semiconductor device 120 may be provided by a potting process. As a result of the potting process, the underfill resin may infiltrate into the space between the flexible substrate 110 and the semiconductor device 120 by surface tension.

The underfill resin may include an epoxy resin, a curing agent, a curing accelerator, an inorganic filler, and combinations thereof. The epoxy resin may include a bisphenol A type epoxy resin, a bisphenol F type epoxy resin, a bisphenol S type epoxy resin, a naphthalene type epoxy resin, a phenol novolac type epoxy resin, a cresol novolac epoxy resin, and the like, and combinations thereof. An amine-based curing agent and an imidazole-based curing accelerator may be used as the curing agent and the curing accelerator, respectively.

In addition, aluminum oxide having a particle size of approximately 0.01 μm to approximately 20 μm may be used as the inorganic filler to improve the thermal conductivity of the underfill layer 150.

Referring to FIG. 8, a heat dissipation layer 130 may be formed on the semiconductor device 120 and the flexible substrate 110 after forming the underfill layer 150 as described above. Formation of the heat dissipation layer 130 may be substantially the same as that described above with respect to FIGS. 2 to 6, additional detailed description thereof will be omitted for the sake of brevity.

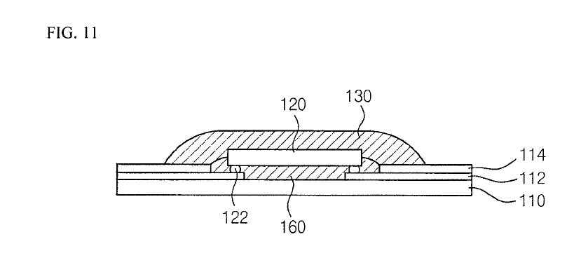

FIGS. 9 to 11 depict schematic cross-sectional views of methods for manufacturing a semiconductor package in accordance with some example embodiments.

Referring to FIGS. 9 and 10, an underfill layer 160 may be formed by coating a first heat dissipation paint composition on a portion of the flexible substrate 110, to which the semiconductor device 120 may be bonded. The semiconductor device 120 may be bonded on the flexible substrate 110 to connect the gold bumps and/or the solder bumps 122 via the underfill layer 160 to the signal lines 112.

Referring to FIG. 11, a heat dissipation layer 130 may be formed by coating a second heat dissipation paint composition on the semiconductor device 120 and the flexible substrate 110. The formation of the heat dissipation layer 130 may be substantially the same as that described above with respect to FIGS. 2 to 6, and additional descriptions thereof are omitted for the sake of brevity. The first heat dissipation paint composition and the second heat dissipation paint composition may be the same and/or substantially the same as those described referring to FIGS. 2 to 6. Thus, additional explanation thereof will be omitted.

In accordance with exemplary embodiments as described above, a heat dissipation layer 130 configured to dissipate heat generated by the semiconductor device 120 may be formed on the flexible substrate 110 and the semiconductor device 120. The flexibility and the adhesiveness of the heat dissipation layer 130 may be improved through the use of epichlorohydrin bisphenol A resin and the modified epoxy resin. The use of heat dissipation filler may provide for improved thermal conductivity of the heat dissipation layer 130.

Therefore, example embodiments may provide a heat dissipation layer 130 that provides increased heat dissipation efficiency from the semiconductor device 120 as compared to conventional technology. Additionally, the improved flexibility and adhesiveness of the heat dissipation layer 130 may reduce the likelihood of separation of the heat dissipation layer 130 from the flexible substrate 110 during use. The use and structure of the heat dissipation layer 130 as provided according to example embodiments may further ensure that the flexible substrate 110 retains flexibility even after application of the heat dissipation layer 130.

Additionally, the dissipation efficiency of heat from the semiconductor device may be further improved by forming an underfill layer 150 or 160 having improved thermal conductivity between the flexible substrate 110 and the semiconductor device 120.

Although the semiconductor package and the method of manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A semiconductor package, comprising:
a flexible substrate provided with signal lines;
a semiconductor device bonded on the flexible substrate and configured to be connected to the signal lines through gold bumps or solder bumps; and
a heat dissipation layer formed on at least a portion of the flexible substrate and at least a portion of the semiconductor device, wherein the heat dissipation layer is formed by:
coating the semiconductor device with a heat dissipation paint composition comprising an epichlorohydrin bisphenol A resin, a modified epoxy resin, a curing agent, a curing accelerator and a heat dissipation filler; and
curing the heat dissipation paint composition.

2. The semiconductor package of claim 1, wherein the heat dissipation paint composition comprises approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator, and wherein a remaining amount of the heat dissipation paint compound comprises the heat dissipation filler.

3. The semiconductor package of claim 1, wherein the modified epoxy resin comprises at least one selected from the group consisting of a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin and a silicon modified epoxy resin.

4. The semiconductor package of claim 1, wherein the curing agent comprises a novolac type phenolic resin.

5. The semiconductor package of claim 1, wherein the curing accelerator comprises an imidazole-based curing accelerator or an amine-based curing accelerator.

6. The semiconductor package of claim 1, wherein the heat dissipation filler comprises aluminum oxide having a particle size of approximately 0.01 μm to approximately 50 μm.

7. The semiconductor package of claim 1, wherein the heat dissipation layer comprises:
a first heat dissipation layer formed on at least one side surface of the semiconductor device and on the flexible substrate; and
a second heat dissipation layer formed on at least a portion of a top surface of the semiconductor device.

8. The semiconductor package of claim 1, further comprising an underfill layer disposed within a space defined between the semiconductor device and the flexible substrate.

9. The semiconductor package of claim 8, wherein the underfill layer is formed at least in part using the heat dissipation compound.

10. A method of manufacturing a semiconductor package comprising:
bonding a semiconductor device on a flexible substrate, wherein the flexible substrate comprises with signal lines and the semiconductor device is configured to be connected to the signal lines through gold bumps or solder bumps;
forming a heat dissipation layer by coating a heat dissipation paint composition on at least a portion of the semiconductor device and on at least a portion of a top surface of the flexible substrate adjacent to the semiconductor device; and
curing the heat dissipation layer,
wherein the heat dissipation paint composition comprises an epichlorohydrin bisphenol A resin, a modified epoxy resin, a curing agent, a curing accelerator and a heat dissipation filler.

11. The method of manufacturing a semiconductor package of claim 10, wherein the forming of the heat dissipation layer comprises:
coating the heat dissipation paint composition on at least a portion of at least one side surface of the semiconductor device and on the flexible substrate; and
coating the heat dissipation paint composition on at least a portion of the top surface of the semiconductor device.

12. The method of manufacturing a semiconductor package of claim 10, wherein the forming of the heat dissipation layer comprises:
positioning a mask on the flexible substrate, wherein the mask defines an opening, and wherein the semiconductor device and the portion of the top surface of the flexible substrate are exposed by the opening; and
filling up the opening with the heat dissipation paint composition using a squeegee.

13. The method of manufacturing a semiconductor package of claim 10, further comprising:
forming an underfill layer filling a space defined between the semiconductor device and the flexible substrate; and
curing the underfill layer.

14. The method of manufacturing a semiconductor package of claim 13, wherein the underfill layer is formed by injecting an underfill resin between the semiconductor device and the flexible substrate.

15. The method of manufacturing a semiconductor package of claim 10, further comprising forming an underfill layer by coating the heat dissipation paint composition on at least an area of the flexible substrate where the semiconductor device is to be bonded prior to bonding the semiconductor device to the flexible substrate,
wherein the semiconductor device is bonded so that the gold bumps or the solder bumps are connected to the signal lines through the underfill layer.

16. The method of manufacturing a semiconductor package of claim 10, wherein the heat dissipation paint composition comprises approximately 1 wt % to approximately 5 wt % of the epichlorohydrin bisphenol A resin, approximately 1 wt % to approximately 5 wt % of the modified epoxy resin, approximately 1 wt % to approximately 10 wt % of the curing agent, approximately 1 wt % to approximately 5 wt % of the curing accelerator, and wherein a remaining amount of the heat dissipation paint composition comprises the heat dissipation filler.

17. The method of manufacturing a semiconductor package of claim 10, wherein the modified epoxy resin comprises at least one selected from the group consisting of a carboxyl terminated butadiene acrylonitrile (CTBN) modified epoxy resin, an amine terminated butadiene acrylonitrile (ATBN) modified epoxy resin, a nitrile butadiene rubber (NBR) modified epoxy resin, acrylic rubber modified epoxy resin (ARMER), an urethane modified epoxy resin and a silicon modified epoxy resin.

18. The method of manufacturing a semiconductor package of claim 10, wherein the curing agent comprises a novolac type phenolic resin.

19. The method of manufacturing a semiconductor package of claim 10, wherein the curing accelerator comprises an imidazole-based curing accelerator or an amine-based curing accelerator.

20. The method of manufacturing a semiconductor package of claim 10, wherein the heat dissipation filler comprises aluminum oxide having a particle size of approximately 0.01 to approximately 50 μm.
